(19) United States
(12) Patent Application Publication
(10) Pub. No.: US 2013/0105456 A1
(43) Pub. Date: May 2, 2013

(54) OPTICALLY-BASED CONTROL FOR DEFROSTING SOLAR PANELS

(71) Applicants: Roger A. Fratti, Mohnton, PA (US); Arlen R. Martin, Blandon, PA (US); Cathy L. Hollien, Bridgewater, NJ (US)

(72) Inventors: Roger A. Fratti, Mohnton, PA (US); Arlen R. Martin, Blandon, PA (US); Cathy L. Hollien, Bridgewater, NJ (US)

(73) Assignee: LSI Corporation, Milpitas, CA (US)

(21) Appl. No.: 13/286,913

(22) Filed: Nov. 1, 2011

(51) Int. Cl. H05K 7/20; H05B 3/20; H05B 1/02

(52) U.S. Cl. 219/209; 219/509; 219/213

(57) ABSTRACT

A solar energy system comprising a defrosting module. The defrosting module includes a first light sensor configured to be located on a solar panel and to produce a first signal which is proportional to the intensity of sunlight reaching the solar panel. The defrosting module includes a second light sensor configured to be located proximate to the solar panel and configured to produce a second signal which is proportional to the intensity of ambient sunlight in the vicinity of the solar panel. The defrosting module includes a control circuit configured to compare the first signal and the second signal and to produce an activation signal when the difference between the first signal and the second signal reaches a threshold value, wherein the activation signal is configured to activate a heater module coupled to the solar panel.

### TECHNICAL FIELD

The invention is directed, in general, to solar energy systems and, more specifically, to a control circuit for, and method of, defrosting solar panels of the system.

### BACKGROUND

Solar energy systems are being increasingly used in both commercial and residential applications to heat water or to generate electricity. The ability of solar energy systems to function optimally depends upon sunlight reaching the solar panels of system. Under certain conditions, however, the solar panels can be become covered, thereby reducing the efficiency of the system.

### SUMMARY

One embodiment of the disclosure is a solar energy system comprising a defrosting module. The defrosting module includes a first light sensor configured to be located on a solar panel and to produce a first signal which is proportional to the intensity of sunlight reaching the solar panel. The defrosting module includes a second light sensor configured to be located proximate to the solar panel and configured to produce a second signal which is proportional to the intensity of ambient sunlight in the vicinity of the solar panel. The defrosting module includes a control circuit configured to compare the first signal and the second signal and to produce an activation signal when the difference between the first signal and the second signal reaches a threshold value, wherein the activation signal is configured to activate a heater module coupled to the solar panel.

Another embodiment of the disclosure is a control circuit for a solar panel defrosting module. The control circuit comprises a comparator configured to receive and compare a first signal from a first light sensor and a second signal from a second light sensor and to produce an activation signal when the difference between the first signal and the second signal reaches a threshold value. The first light sensor is configured to be located on a solar panel and to produce the first signal which is proportional to the intensity of sunlight reaching the solar panel. The second light sensor configured to be located proximate to the solar panel and to produce the second signal which is proportional to the intensity of ambient sunlight in the vicinity of the solar panel. The activation signal is configured to activate a heating element coupled to the solar panel.

Still another embodiment of the disclosure is a method of defrosting a solar energy system. The method comprises measuring the intensity of sunlight reaching a solar panel of the system and measuring the intensity of ambient sunlight in the vicinity of the solar panel. The method also comprises determining the difference in the intensity of the sunlight reaching the solar panel and the intensity of the ambient sunlight. The method further comprises activating a heater module coupled to the solar panel when the difference between the intensity of the sunlight reaching the solar panel and the intensity of the ambient sunlight reaches a threshold value.

### BRIEF DESCRIPTION OF THE DRAWINGS

Reference is now made to the following descriptions taken in conjunction with the accompanying drawings, in which:

FIG. 1 presents a design layout of an example embodiment of a solar energy system of the disclosure;

FIG. 2 presents a block diagram of an example control circuit of the disclosure, such as any of the control circuits used in the system disclosed in the context of FIG. 1; and

FIG. 3 presents a flow diagram of an example embodiment of a method for defrosting a solar energy system, such as any example embodiments of the solar energy systems, or, as implemented by the example control circuits, as discussed in the context of FIGS. 1 and 2, respectively.

### DETAILED DESCRIPTION

For the purposes of the present disclosure, the term, “or,” as used herein, refers to a non-exclusive or, unless otherwise indicated.

Embodiments of the present disclosure benefit from the recognition that during certain weather conditions, the solar panels of solar energy systems can become covered with frozen precipitation (e.g., frost, snow, ice), and consequently, sunlight does not reach the solar panel. The occurrence of such an event can be identified by comparing the amount of sunlight reaching the solar panel to the amount of ambient sunlight surrounding the solar panel. When the difference between the intensity of sunlight reaching the solar panel versus the ambient sunlight exceeds a threshold value, measures can be taken to defrost the solar panels.

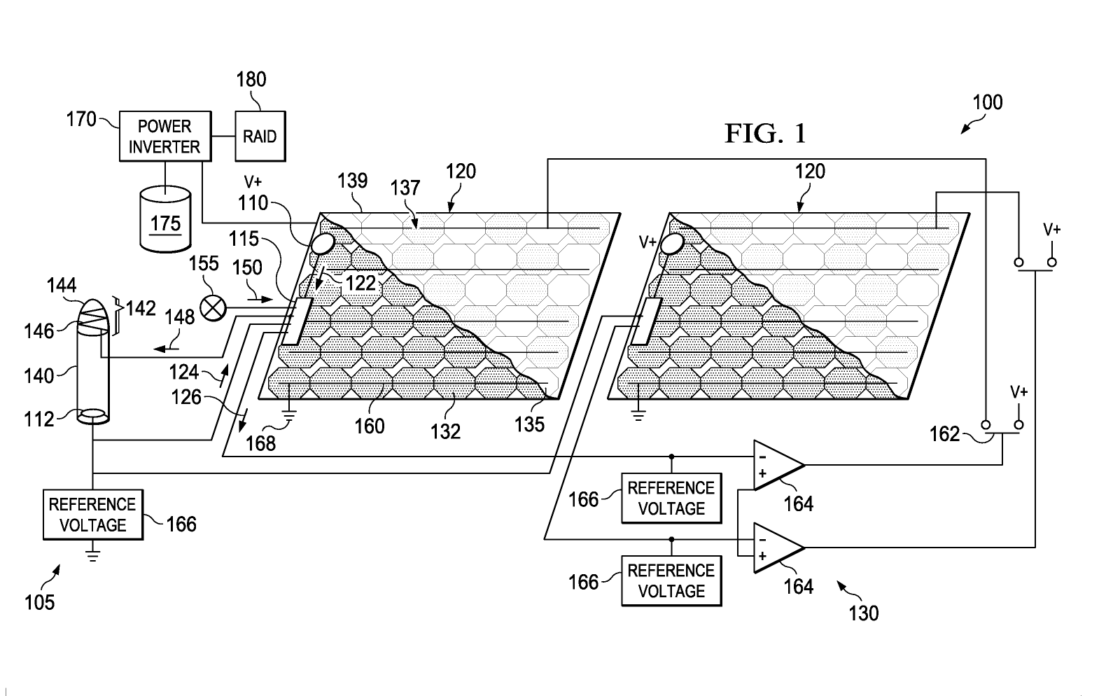

One embodiment of the present disclosure is a solar energy system. FIG. 1 presents a design layout of an example embodiment of a solar energy system 100 of the disclosure. The system 100 comprises a defrosting module 105, which includes a first light sensor 110, a second light sensor 112 and a control circuit 115. The first light sensor 110 is configured to be located on a solar panel 120 of the system 100 and to produce a first signal 122 which is proportional to the intensity of sunlight reaching the solar panel 120. The second light sensor 112 is configured to be located proximate to the solar panel 120 and also configured to produce a second signal 124 which is proportional to the intensity of ambient sunlight in the vicinity of the solar panel 120. The control circuit 115 is configured to compare the first signal 122 and the second signal 124 and to produce an activation signal 126 when the difference between the first signal 122 and the second signal 124 reaches a threshold value. The activation signal 126 is configured to activate a heater module 130 coupled to the solar panel 120.

The term defrosting module as used herein, refers to the functional assembly of components (e.g., light sensors 110, 115, circuit 115, and other optional components) to accomplish defrosting of solar panels. In some cases, the components are collocated in a self-contained assembly, while in other cases, the components are separately located. In some cases the module 105 can be a functional assembly of components that are attached to a previously installed system 100 (e.g., a retrofit to a system with no defrosting capabilities), while in other cases, the module 105 can integrated into the manufacture of a new system 100. The phrase, locating the second light sensor 112 proximate to the solar panel, as used herein, refers to the placement of the second light sensor 112 such that, the amount of sunlight capable reaching the second light sensor 112) is substantially the same as the amount of sunlight that could reach the solar panel 120 (e.g., such as measured by the first light sensor 110), in the absence of frozen precipitation covering the solar panel 120. For instance, in some cases, the solar panel 120 is fixedly mounted on a roof top of a building with a particular orientation with respect to the sun. In such cases, the second light sensor 112, can be fixedly mounted on the same roof top, with the same orientation with respect to the sun, as the solar panel. For instance, in some cases, the solar panel 120 is rotatably mounted on a roof top of a building such that the solar panel's orientation changes as a function of the time-of-day or date (e.g., time-of-year), so as to optimize the amount of sunlight reaching the solar panel throughout the day or throughout the year. In such cases, the second light sensor 112, can be also be rotatably mounted on the same roof top, with the same orientation changing with respect to the sun, as the solar panel. For instance, in some cases, at a certain time-of-day or date, sunlight reaching the solar panel 120 can be temporarily obstructed by other structures (e.g., other structures on the roof, other buildings or trees surrounding the roof top). In such cases, the second light sensor 112 can be mounted so as to have the same obstruction of sunlight reaching the sensor 112 at substantially the time-of-day or date. Based on the present disclosure, one of ordinary skill would appreciate how to locate the second light sensor 112 proximate to the solar panel 120.

In some cases, one or both the first and second signals 122, 124 can be electrical signals (e.g., an electrical current) carried by a wired connection from the first and second light sensors 110, 112, respectively, to the control circuit 115. In other cases, one or both the first and second signals 122, 124 can be wireless signals (e.g., radiofrequency or microwave radiation) transmitted by the first and second light sensors 110, 112, respectively, and received by the control circuit 115. Similarly, the activation signal 126 can be an electrical signal carried by a wired connection between the circuit 115 and the heater module 130, or, a wireless signal transmitted from the circuit 115 to the heater module 130. Based on the present disclosure, one of ordinary skill would appreciate the various ways to send the signals 122, 124, 126 to and from the first and second light sensors 110, 112, the control circuit 115 and the heater module 130.

In some embodiments, the solar panel 120 is a photovoltaic panel in the solar energy system 100 configured as a photovoltaic system. For instance, the system 100 can be configured to supply electricity in commercial or residential applications, with the panel 120 including photovoltaic cells 132 and transparent cover layer 135 (shown in FIG. 1 as partially removed so that underlying features can be depicted). Embodiments of the cells 132 include mono- or multi-crystalline silicon or other photoactive material layers familiar to those skilled in the art. The cover layer 135 can be configured to protect cells 132 from mechanical damage, allow the passage light at frequencies that the cells 132 are most sensitive to, and in some case may be configured to concentrate the sunlight reaching the cells 132.

In some embodiments, the solar panel 120 is a solar hot water heating panel in the solar energy system 100 configured as convection heat storage system. For instance, the system 100 can be configured to supply hot water, or other fluid, in commercial or residential applications, with the panel 120 including pipes configured to circulate fluid there-through, the fluid actively or passively circulated to and from a storage tank of the system 100.

As further illustrated in FIG. 1, in some embodiments, the first light sensor 110 can be embedded within the solar panel 120. For instance, in some cases, the first light sensor 110 can be located between the photovoltaic cells 132 and the transparent cover layer 135. Such embodiments protect the sensor 110 from mechanical damage but still allow substantially the same intensity of sunlight to reach the sensor 110 as reaching the active portion (e.g., the cells 132) of the panel 120. In other cases, the first light sensor 110 could be mounted to an external surface 137 of the panel 120 (e.g., the surface oriented to face the sun) or to a side 139 of the panel 120 (e.g., so as to have substantially the same orientation with respect to the sun as the external surface 137 facing the sun). Such embodiments may be advantageous for embodiments where the defrost module 105 is a retrofit addition to a previously installed system 100, or in other situations where it would be inconvenient to embed the sensor 110 in the panel 120.

As also illustrated in FIG. 1, in some embodiments, the control circuit 115 can be co-located with the first light sensor 110. For instance, when the first light sensor 110 is embedded within the solar panel 120 the control circuit 115 can also be embedded in the panel 120, e.g., adjacent to or nearby the sensor 110. Or, when the when the first light sensor 110 is mounted to the external surface 137 or side 139 of the panel 120 the control circuit 115 can also be mounted to the external surface 137 or side 139, e.g., adjacent to or nearby the sensor 110. Such embodiments can advantageously provide the same protection of the circuit 115 against mechanical damage and/or minimize the additional components to facilitate communication of the signal 122 between the sensor 110 and the circuit 115.

In some embodiments, the second light sensor 112 is configured so as to not be subject to coverage by frozen precipitation. Such embodiments facilitate the second light sensor 112 receiving ambient sunlight in the vicinity of the solar panel 120, and thereby produce the second signal 124 which is proportional to the intensity of ambient sunlight in the vicinity of the panel 120.

For instance in some embodiments the second light sensor 112 can be located at an elevation that is higher than the elevation of panel 120, e.g., so that snowfall which accumulates on the panel will not accumulate on second light sensor 112.

For instance, as illustrated in FIG. 1, in some cases, the second light sensor 112 can be located in a tube 140 (e.g., at the bottom of, a tube 140) that is configured to direct the ambient sunlight to the sensor 112. Locating the second light sensor 112 in the tube 140 can help prevent frozen precipitation, such as snow, from covering the sensor 112. In some cases, a top end 142 of the tube 140 is located above the solar panel 120, e.g., so that snowfall will not accumulate on the top end 142 of the tube 140. In some cases, the top end 142 includes a rounded exterior surface 144, e.g., so that snow will not stably rest on the top end 142. Based on the present disclosure one of ordinary skill would appreciate the top end 142 could include other shapes such as pyramidal, vertically beveled, vertically angled, or other shapes to deter the accumulation of frozen precipitation thereon.

For instance, as further illustrated in FIG. 1, in some cases, the tube 140 can further include a second heating element 146 that is configured to heat the top end 142 of the tube 140 when the ambient temperature is below a pre-defined frost threshold. In some cases, e.g., the control circuit 115 can be further configured to send a second activation signal 148 to the second heater module 146 when the temperature is below a temperature at which frost formation is likely to occur.

In some embodiments, the control circuit 115, is further configured to receive a third signal 150 which is proportional to an ambient temperature in the vicinity of the solar panel 120 and to suppress producing the activation signal when the ambient temperature is above a frost threshold. In some cases, the frost threshold can be a preselected value equal to the freezing point of water. In other cases, the frost threshold can be an adjustable value that ranges from the freezing point of water to several degrees centigrade below the freezing point of water dependent upon the relative humidity of the air surrounding the solar panel.

In some cases, the control circuit 115 can be configured to receive the third signal 150 from a wireless transmission of information containing, temperature, or temperature and humidity data, for the vicinity (e.g., county, city or district) where the solar panel 120 is located. For instance, the control circuit 115 can be configured to receive such information sent by a telecommunications network such as a cellular wireless network coupled to or part of the circuit 115.

In other cases, the module 105 can further include a temperature sensor 155 configured to generate the third signal 150 proportional to an ambient temperature in the vicinity of the solar panel. The control circuit 150 can be configured to receive the third signal 150 from the temperature sensor 155, and suppress producing the activation signal 126 to the first heater module 130, and/or send the second activation signal 148 to the second heater module 146, such as discussed above.

As also illustrated in FIG. 1, in some embodiments, the system 100 can include a plurality of the solar panels 120 (e.g., an array of panels 120, in some cases) and each one of the solar panels 120 can include at least one first light sensor 110 and a control circuit 115 coupled thereto. For instance, each one of the panels 120 can have one or more first light sensors 110 and the co-located circuit 115 embedded therein, or attached thereto. In other cases, however, each one of the solar panels is coupled to the control circuit, with the circuit 115 mounted in a location that is separate from the solar panels 120. For instance, each one of the panels 120 can have one or more first light sensors 110, and, there can be a single circuit 115 that is not in or on any of the panels 120, but is configured the receive the first sensor signal 122 from each of the panels 120, as well as the second sensor signal 122. Having a single separate control circuit 115 can be advantageous in instances where there is a need to service the circuit 115 (e.g., trouble-shoot, replace, or update firmware).

In some cases, the heater module 130 can be on, or integrated into, the solar panel 120. For instance, heater elements 160 (e.g., metal wires or flat strips) of the heater module 130 can be located between two cover layers 135 of the panel, or located on the external surface 137 of the panel 120. In some cases, the heater module 130 can be configured to have a power consumption value in a range from 10 to 200 Watts, and in some cases, from 50 to 70 Watts.

One of ordinary skill would be familiar with the electronic circuitry to provide electrical power to the heater module 130. For instance, in some embodiment, the heater module 130 can include the heater elements 160 associated with each of the panels 120, separate MOS sample switches 162 connected to the heater elements 160, and separate comparator components 164, connected to MOS sample switches 162. Each comparator component 164 can receive the activation signal 126 (e.g., an input voltage) from the circuit 115. A reference voltage 166 can be applied in parallel with the activation signal 126 to adjust the input (e.g., adjust the input voltage) to the comparator component 164. There can be ground connections 168 to the first and second light sensors 110, 112, the circuit 115 and the heater modules 130. Based on the present disclosure, one of ordinary skill would appreciate that the heater module 130 could have various other configurations.

Some embodiments of the heater module 130 include one or more electrically conductive heater elements 160 (e.g., nickel-chromium alloy wires) arranged on the panel 120 such that when a current is passed through the wires, the external surface 137 of the panel 120 that is oriented to receive sunlight is heated to a temperature that is higher enough (e.g., 1 to 5° C.) to rapidly melt frozen precipitation on the panel 120 but not damage components of the module 105 (e.g., the sensor 110 or circuit 115). In some embodiments, the wires 160 are selected to have a gauge (e.g., 20 gauge or higher) that facilitates rapid heating while at the same time only blocks a relatively small portion of the total area of the external surface 137 oriented to receive sunlight (e.g., less than about 0.1%, or in some cases less than about 0.01% and in some cases less than about 0.001%).

As further illustrated in FIG. 1, some embodiments of the system 100 can further include a power inverter 170 configured to convert direct current from the panel 120 to an alternating current. For instance, each of a plurality of solar panels 120 can wired together to provide a direct current which is sent to the power inverter 170.

Some embodiments of the system 100 can further include an energy storage module 175 configured to receive and store energy collected from the panel 120. For instance, in some cases, the energy storage module 175 can include one or more batteries and/or ultra-capacitors configured to receive a direct current from the panel 120, or a plurality of the panels 120.

In some cases, the system 100 can be configured to provide backup electrical power to any electrically powered system, such as digital data storage system 180. For instance, electrical power from the solar panel 120 can provide electrical power to a Redundant Array of Independent Disks (RAID) storage system 180. The electrical power from the panel can be supplied via the inverter 170 from a battery or ultra-capacitor 170 that has been charged from the panel 120.

In some cases, the heater module 130, and/or second heater module 146, can be powered from power collected from the solar panel 120 or other panels of the system 100, e.g., as stored in the energy storage module 175, while in other cases, the heater module 130 can be powered from an external power source.

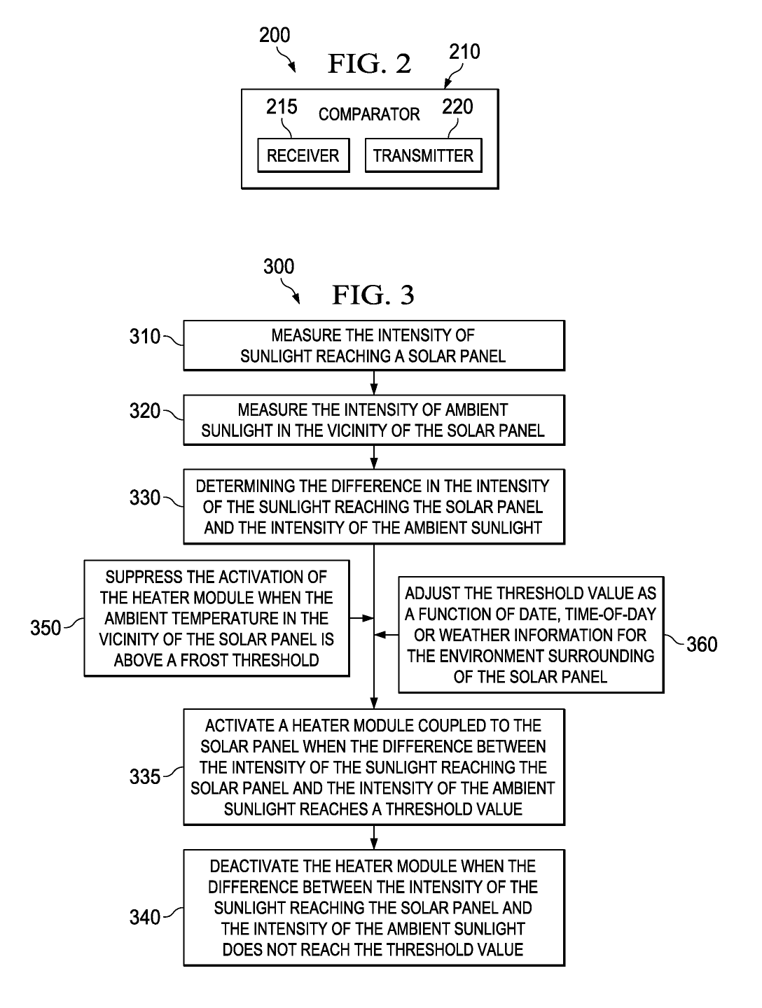

Another embodiment of the disclosure is a control circuit for a solar panel defrosting module. FIG. 2 presents a block diagram of an example control circuit 200 of the disclosure, such as any of the control circuits 115 used in the system disclosed in the context of FIG. 1.

With continuing reference to FIGS. 1 and 2 throughout, the control circuit 200 comprises a comparator 210 configured to receive and compare a first signal 122 from a first light sensor 110 and a second signal 124 from a second light sensor 112 and to produce an activation signal 126 when the difference between the first signal 122 and the second signal 124 reaches a threshold value. As noted in the context of FIG. 1, the first light sensor 110 is configured to be located on a solar panel 120 and to produce the first signal 122, which is proportional to the intensity of sunlight reaching the solar panel 120, and, the second light sensor 112 is configured to be located proximate to the solar panel 120 and to produce the second signal 124, which is proportional to the intensity of ambient sunlight in the vicinity of the solar panel 120. The activation signal 126 is configured to activate a heating element 130 coupled to the solar panel 120.

For instance, the difference in light intensity reaching the light sensors 110, 112 will increase when the first sensor is covered by frozen precipitation and the second sensor is not. Consequently, there would be a large difference in the first and second signals 122, 124; when the difference exceeds a threshold value, the activation signal 126 is initiated by the circuit 115.

In some embodiments, the comparator 210 is further configured to produce a deactivation signal when the difference between the first signal 122 and the second signal 124 does not reach the threshold value. For instance, as frozen precipitation is melted by the activated heater module 130, the difference in light intensity reaching the first and second light sensors 110, 112 diminishes and when the that difference drops below a threshold value the deactivation signal can be initiated to stop sending power to the heater module 130.

In some embodiments, the comparator 210 is further configured to receive another signal containing date, time-of-day or weather information for the environment surrounding of the solar panel 120. In some cases the signal containing the date, time-of-day or weather information is received from a transmission that is external to the defrost module 105 or system 100. For example the containing date, time-of-day can be contained in a radiofrequency signal transmitted by the U.S. National Bureau of Standard and Technology. In some cases, the signal containing the date, time-of-day or weather information is received from a transmission that is part of the defrost module 105 or system 100. For instance, the signal to the comparator 210 can include a third signal 150 from a temperature sensor 155 that is part of the module 105.

In some cases, the comparator 210 is further configured to change the activation threshold depending on the time-of-day and/or date. In some cases, the comparator 210 is configured to suppress the activation signal 126 when the weather information (e.g., ambient temperature and humidity data) indicates that the environment surrounding of the solar panel 120 is above a frost formation threshold.

One of ordinary skill would be familiar with the various circuit components needed to accomplish the functions of the circuit 115 as disclosed herein. In some cases, for example, the comparator 210 includes, or is, a micro-processing unit configured to receive the first and second signals 122, 124 (e.g., voltages), perform the comparison of the first and second signals 122, 124 (e.g., calculate the voltage difference), and transmit the activation signal 126 (e.g., a voltage) to the heater module 130 (e.g., an comparator component 164 of the heater module 130).

In some embodiments, the circuit 115 can further include a receiver subunit 215 configured to the first and second signals 122, 124, and, a transmitter subunit 220 configured to transmit the activation signal 126. In some embodiments the receiver subunit 215 and transmitter subunit 220 can be part of the comparator 210 while in other embodiments the receiver subunit 215 and transmitter subunit 220 can be separate from the comparator 210 but configured to provide input to, and receive output from, the comparator. In some embodiments, the receiver subunit 215 and transmitter subunit 220 can be combined (e.g., because they share at least some circuit components) as a transceiver subunit.

In some cases, one or both of the receiver subunit 215 and transmitter subunit 220 are configured to receive the first and second signals 122, 124 from a wired connection between the light sensors 110, 112 and the circuit 115, or, between the circuit 115 and the heater module 130. For instance, in some cases, the receiver subunit 215 and/or transmitter subunit 220 can include terminals for the wired connections to and from the circuit. In other cases, one or both of the receiver subunit 215 and transmitter subunit 220 are configured to receive the first and second signals 122, 124 from a wireless connection between the light sensors 110, 112 and the circuit 115, or, between the circuit 115 and the heater module 130. For instance, in some cases, the receiver subunit 215 and/or transmitter subunit 220 can include antenna to facilitate, e.g., radiofrequency or microwave reception and transmission.

Another embodiment of the disclosure is method of defrosting a solar energy system. FIG. 3 presents a flow diagram of an example embodiment of a method 300 for defrosting a solar energy system, such as any example embodiments of the solar energy systems, or, as implemented by the example control circuits, as discussed in the context of FIGS. 1 and 2, respectively.

As illustrated in FIG. 3, the method 300 comprises a step 310 of measuring the intensity of sunlight reaching a solar panel 120 of the system 100, e.g., using the first light sensor 110. The method 300 also comprises a step 320 of measuring the intensity of ambient sunlight in the vicinity of the solar panel 130, e.g., using the second light sensor 112. The method 300 further comprises a step 330 of determining, e.g., via a control circuit 115, the difference in the intensity of the sunlight reaching the solar panel 120 and the intensity of the ambient sunlight, e.g., by comparing signals 122, 124 from the first and second light sensors, 110, 112, respectively. The method 300 also comprises a step 335 of activating, e.g., via a signal 126 from the circuit 115, a heater module 130 coupled to the solar panel 120 when the difference between the intensity of the sunlight reaching the solar panel 120 and the intensity of the ambient sunlight reaches a threshold value.

As further illustrated in FIG. 3, some embodiments of the method 300, include a step 340 of deactivating the heater module when the difference between the intensity of the sunlight reaching the solar panel and the intensity of the ambient sunlight does not reach the threshold value. However, in other embodiments the activation of the heater module 130 can be automatically terminated after a predefined period. For instance, the circuit 115 can be configured to stop sending the activation signal 126 after a preset time interval such as 30, 60, or 120 minutes. Such embodiments can advantageously minimize the amount of energy used to defrost the panel 120, or, prevent overheating of the module 105 or the panel 120, in instances where the threshold value was reached due to conditions not caused by the accumulation of frozen precipitation on the panel 120. An example of such conditions is where dust or other debris accumulates on the panel 120, thereby causing a difference between the intensity of the sunlight reaching the solar panel and the intensity of the ambient sunlight that reaches the threshold value.

As also illustrated in FIG. 3, some embodiments of the method 300 include a step 350 of suppressing the activation of the heater module 130 when the ambient temperature in the vicinity of the solar panel 120 is above a frost threshold. For instance, the control circuit 115 can be configure such that when the ambient temperature, e.g., as measured by a temperature sensor 155 and reported to the circuit 115, e.g., via the third signal 150, the activation signal 126 is not sent to the heater module 130. Such embodiments can advantageously prevent the needless use of energy to defrost the panel 120 such as when the reaches the threshold value is reached due to the accumulation of dust or other debris on the panel 120, and not due the accumulation of frozen precipitation.

As also illustrated in FIG. 3, some embodiments of the method 300 include a step 360 of adjusting the threshold value as a function of date, time-of-day or weather information for the environment surrounding of the solar panel 120. For instance, as discussed in the context of FIG. 1, the circuit 115 can be configured adjust the threshold in order to account for changes in the formation of frost on the panel, e.g., due to changes in the relative humidity and temperature surrounding the panel 120. For instance, as discussed in the context of FIG. 2, the circuit 115 can be configured adjust the threshold in order to account for expected changes in the difference between the intensity of the sunlight reaching the solar panel and the intensity of the ambient sunlight. For example, there can be anticipated different intensities of sunlight potentially reaching the panel at different times of year or day due to the changes in the orientation of the panel 120 relative to the sun.

Those skilled in the art to which this application relates will appreciate that other and further additions, deletions, substitutions and modifications may be made to the described embodiments.

What is claimed is:

1. A solar energy system, comprising:
a defrosting module, including:
a first light sensor configured to be located on a solar panel and to produce a first signal which is proportional to the intensity of sunlight reaching the solar panel;
a second light sensor configured to be located proximate to the solar panel and configured to produce a second signal which is proportional to the intensity of ambient sunlight in the vicinity of the solar panel; and
a control circuit configured to compare the first signal and the second signal and to produce an activation signal when the difference between the first signal and the second signal reaches a threshold value, wherein the activation signal is configured to activate a heater module coupled to the solar panel.

2. The system of claim 1, wherein the solar panel is a photovoltaic panel in the solar energy system configured as a photovoltaic system.

3. The system of claim 1, wherein the solar panel is a solar hot water heating panel in the solar energy system configured as convection heat storage system.

4. The system of claim 1, wherein the first light sensor is embedded within the solar panel.

5. The system of claim 1, wherein the control circuit is co-located with the first light sensor.

6. The system of claim 1, wherein the second light sensor is configured so as to not be subject to coverage by frozen precipitation.

7. The system of claim 1, wherein the second light sensor is located in a tube that is configured to direct the ambient sunlight to the second light sensor.

8. The system of claim 7, wherein a top end of the tube is located above the solar panel and the top end of the light tube includes a rounded exterior surface.

9. The system of claim 7, wherein the tube includes a second heating element configured to heat a top end of the tube when the ambient temperature is below a pre-defined frost threshold.

10. The system of claim 1, wherein the control circuit is further configured to receive a third signal which is proportional to an ambient temperature in the vicinity of the solar panel and to suppress producing the activation signal when the ambient temperature is above a frost threshold

11. The system of claim 1, further including a temperature sensor configured to generate a third signal which is proportional to an ambient temperature in the vicinity of the solar panel, and wherein the control circuit is configured to receive the third signal.

12. The system of claim 1, further including a plurality of the solar panels wherein each one of the solar panels includes at least one of the first light sensors and the control circuit coupled thereto.

13. The system of claim 1, further including a plurality of the solar panels wherein each one of the solar panels is coupled to the control circuit, the control circuit mounted in a location that is separate from the solar panels.

14. The system of claim 1, wherein electrical power from the solar panel provides electrical power to a Redundant Array of Independent Disks storage system.

15. A control circuit for a solar panel defrosting module, comprising:
a comparator configured to receive and compare a first signal from a first light sensor and a second signal from a second light sensor and to produce an activation signal when the difference between the first signal and the second signal reaches a threshold value, wherein:
the first light sensor is configured to be located on a solar panel and to produce the first signal which is proportional to the intensity of sunlight reaching the solar panel,
the second light sensor configured to be located proximate to the solar panel and to produce the second signal which is proportional to the intensity of ambient sunlight in the vicinity of the solar panel, and
the activation signal is configured to activate a heating element coupled to the solar panel.

16. The circuit of claim 15, wherein the comparator includes a micro-processing unit configured to receive the first and second signals, perform the comparison of the first and second signals, and transmit the activation signal.

17. The circuit of claim 15, wherein the comparator is further configured to produce a deactivation signal when the difference between the first signal and the second signal does not reach the threshold value.

18. The circuit of claim 15, wherein the comparator is further configured to receive another signal containing date, time-of-day or weather information for the environment surrounding of the solar panel.

19. A method of defrosting a solar energy system, comprising:
measuring the intensity of sunlight reaching a solar panel of the system;
measuring the intensity of ambient sunlight in the vicinity of the solar panel;
determining the difference in the intensity of the sunlight reaching the solar panel and the intensity of the ambient sunlight; and
activating a heater module coupled to the solar panel when the difference between the intensity of the sunlight reaching the solar panel and the intensity of the ambient sunlight reaches a threshold value.

20. The method of claim 19, further including deactivating the heater module when the difference between the intensity of the sunlight reaching the solar panel and the intensity of the ambient sunlight does not reach the threshold value.
